(19) United States
(12) Patent Application Publication
(10) Pub. No.: US 2026/0366137 A1
(43) Pub. Date: Nov. 19, 2026

(54) PHYSICAL VAPOR DEPOSITION SPUTTERING TARGET

(71) Applicant: Applied Materials, Inc., Santa Clara, CA (US)

(72) Inventors: Madan Kumar SHIMOGA MYLARAPPA, Bengaluru (IN); Jiao SONG, Singapore (SG); Kirankumar Neelasandra SAVANDAIAH, Bangalore (IN); Yuichi WADA, Chiba (JP); Felix DENG, Singapore (SG); Jian Wei LOO, Singapore (SG)

(21) Appl. No.: 19/676,045

(22) Filed: May 13, 2026

Related U.S. Application Data
(63) Continuation of application No. PCT/US2024/046936, filed on Sep. 16, 2024.

(51) Int. Cl. C23C 14/34; H01J 37/34

(52) U.S. Cl. CPC C23C 14/3407; H01J 37/3423; H01J 2237/332

(57) ABSTRACT

A sputtering target is disclosed having a material to be sputtered having a central planar region, the central planar region having a tapered peripheral edge region which terminates at an upper outer edge, wherein a portion of the tapered peripheral edge comprises a roughened portion have an average roughness (Ra) of greater than or equal to 60 micrometers. A substrate processing apparatus which includes the sputtering target is also disclosed.

### CROSS-REFERENCE TO RELATED APPLICATIONS

This application claims priority to International Patent Application No. PCT/US2024/046936, filed Sep. 16, 2024, and entitled “PHYSICAL VAPOR DEPOSITION SPUTTERING TARGET”, the contents of which are hereby incorporated by reference in its entirety.

### FIELD

Embodiments of the present disclosure generally relate to semiconductor processing equipment.

### BACKGROUND

Physical vapor deposition (PVD) is commonly utilized for forming thin layers of material on substrates, for example semiconductor substrates. A sputtering target is provided proximate to a substrate within a chamber. During physical vapor deposition processes, the sputtering target typically does not get consumed uniformly. For example, the outer edge portion of the target typically does not erode during normal operation and materials sputtered from other portions of the target can get redeposited on the outer edge of the sputtering target. Over time, the accumulated, redeposited material will eventually flake-off, also referred to as peeling. The material peeling off of the target can undesirably reach the substrate surface and generate particles on films being deposited on the substrate.

Accordingly, the inventors have provided a target that may advantageously reduce the peeling and other issues associated with a PVD sputtering target.

### SUMMARY

A sputtering target and apparatus for PVD are provided herein. In embodiments, a sputtering target comprises a material to be sputtered having a central planar region, the central planar region having a tapered peripheral edge region which terminates at an upper outer edge, wherein a portion of the tapered peripheral edge comprises a roughened portion have an average roughness (Ra) of greater than or equal to 60 micrometers.

In embodiments, a sputtering target comprises a material to be sputtered including a central planar region having a tapered peripheral edge which terminates at an upper outer edge located above a lower outer edge of the central planar region; a backing plate having the material to be sputtered disposed thereon and comprising a peripheral region located adjacent to and surrounding the lower outer edge of the material to be sputtered, wherein a thickness of the central planar region is greater than a thickness of the upper outer edge, wherein the upper outer edge overhangs a portion of the peripheral region comprising the material to be sputtered; and a roughened portion comprising a portion of the tapered peripheral edge and at least a portion of the peripheral region comprising the material to be sputtered, having an average roughness (Ra) of greater than or equal to 60 micrometers.

In embodiments, a substrate processing apparatus comprises a chamber body; a lid disposed atop the chamber body; a target assembly coupled to the lid, the target assembly including a sputtering target according to any embodiment disclosed herein.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic view of a sputtering target mounted on a backing plate according to embodiments disclosed herein.

FIG. 2 depicts a side view of a sputtering target mounted on a backing plate according to embodiments disclosed herein.

FIG. 3 depicts an enlarged view of section A depicted in FIG. 2.

FIG. 4 depicts an enlarged view of section B depicted in FIG. 3.

FIG. 5 depicts a cross-sectional side view of the backing plate showing the contact pad recess for receiving a contact pad according to embodiments disclosed herein.

FIG. 6 depicts a top view of a contact pad in accordance with some embodiments disclosed herein.

FIG. 7 depicts a rear view of the backing plate shown in FIG. 2.

FIG. 8 depicts a process chamber having a target assembly in accordance with some embodiments disclosed herein.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a sputtering target are provided herein. In embodiments, a sputtering target comprises a material to be sputtered having a central planar region, the central planar region having tapered peripheral edge region which terminates at an upper outer edge, wherein a portion of the tapered peripheral edge comprises a roughened portion have an average roughness (Ra) of greater than or equal to 60 micrometers. In embodiments, a thickness of the central planar region is greater than a thickness of the upper outer edge. In embodiments, the sputtering target further comprises a lower outer edge, wherein the upper outer edge overhangs the lower outer edge. In embodiments, the sputtering target further comprises a backing plate having the material to be sputtered disposed thereon and having a diameter greater than that of the material to be sputtered, wherein the roughened portion further includes a peripheral portion of the backing plate located adjacent to, and surrounding the tapered peripheral edge region, and having an average roughness (Ra) of greater than or equal to 63.5 micrometers.

In embodiments, the upper outer edge overhangs a portion of the backing plate. In embodiments, the backing plate further comprises a plurality of recesses formed therein, dimensioned and arranged to accommodate a plurality of low-friction pads partially disposed in the plurality of recesses. In embodiments, the roughened portion comprises a series of peaks separated by valleys, the series of peaks having an average height of at least 100 nm above the valleys, which in embodiments, is flow formed. In embodiments, the roughened portion has an average roughness (Ra) of greater than or equal to 63.5 micrometers. In embodiments, the roughened portion comprises a knurled pattern, which in embodiments, is a diamond knurled pattern.

In embodiments, the backing plate of the sputtering target further comprises a plurality of cooling channels disposed therein. In embodiments, the plurality of cooling channels comprise a plurality of concentric rings and/or a plurality of linear channels, each extending radially outward from an inner portion to an outer portion of the sputtering target.

In embodiments, a substrate processing apparatus comprises a chamber body; a lid disposed atop the chamber body; and a target assembly coupled to the lid, the target assembly including a sputtering target according to one or more embodiments disclosed herein.

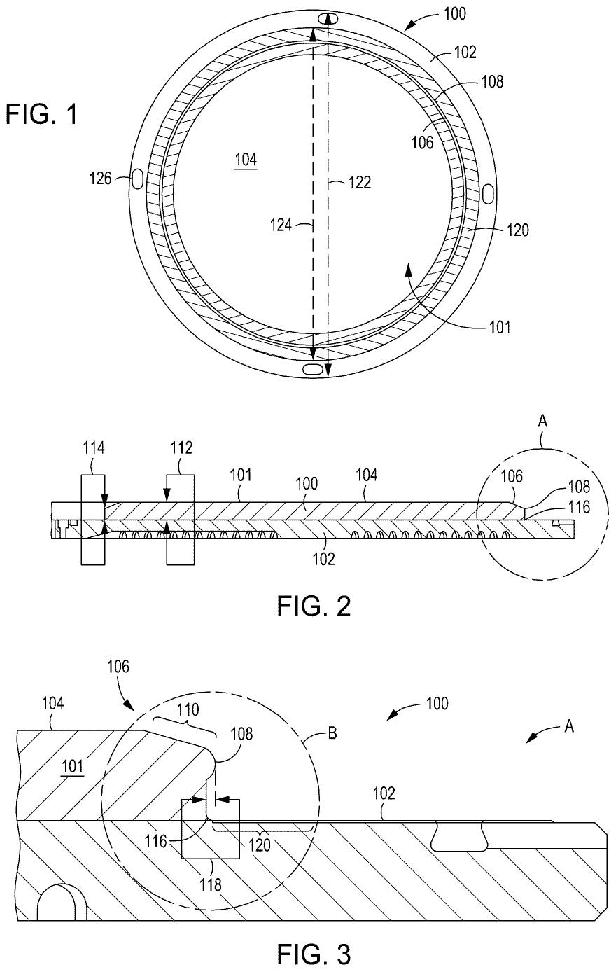

FIG. 1 depicts a schematic view of a sputtering target 100 comprising the material to be sputtered 101 mounted on a backing plate 102 according to embodiments disclosed herein. In embodiments, sputtering target 100 comprises a central planar region 104. In embodiments, the central planar region 104 has a tapered peripheral edge region 106 which terminates at an upper outer edge 108. In embodiments, a portion of the tapered peripheral edge region 106 comprises a roughened portion 110 having an average roughness (Rₐ) of greater than or equal to 60 micrometers.

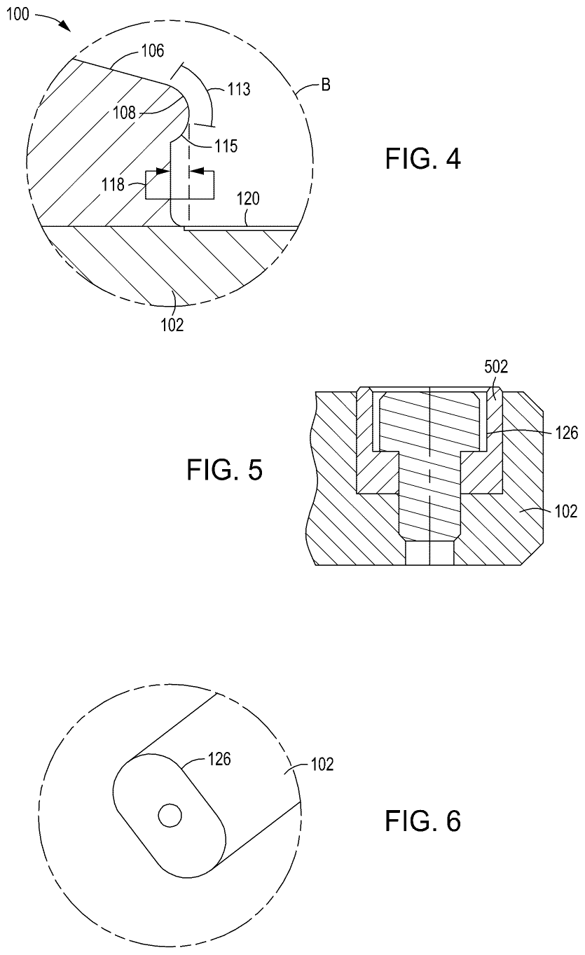

As depicted in FIG. 2, a thickness 112 of the central planar region 104 of the sputtering target 100 is greater than a thickness 114 of the upper outer edge 108 of the tapered peripheral edge region 106. In other words, the tapered peripheral edge region 106 is tapered down towards the lower outer edge 116 located at the bottom of the sputtering target 100. As depicted in FIG. 2 and shown in greater detail in FIG. 3 and FIG. 4, in embodiments, the upper outer edge 108 overhangs 118 the lower outer edge 116 of the sputtering target 100, which in embodiments, is located where the sputtering target 100 meets an upper surface of the backing plate 102.

As depicted in FIGS. 1 and 3, in embodiments, the sputtering target 100 is mounted on a backing plate 102 and the backing plate 102 further comprises the material to be sputtered 101 disposed thereon and has a diameter 122 greater than a diameter 124 of the material to be sputtered 101. The roughened portion 110 further includes a peripheral portion 120 of the backing plate 102 located adjacent to and surrounding the tapered peripheral edge region 106. In embodiments, the roughened portion 110 which includes peripheral portion 120 has an average roughness (Rₐ) of greater than or equal to 60 micrometer, or greater than or equal to 63.5 micrometers, or greater than or equal to 65 micrometers.

As depicted in FIGS. 2, 3, and 4, in embodiments, the upper outer edge 108 overhangs a portion of the backing plate 102. In embodiments, the upper outer edge 108 comprises a rounded portion 113 which terminates in an angled portion 115 dimensioned and arranged to facilitate roughening of the surface.

In embodiments, the backing plate 102 further comprises a plurality of recesses 126 formed therein. As shown in FIGS. 5 and 6, in embodiments, each of the recesses 126 are dimensioned and arranged to accommodate a plurality of low friction pads 502 partially disposed in each of the plurality of recesses 126. The recesses 126 are dimensioned and arranged to cooperate with the low friction pads 502 to allow for thermal expansion of the sputtering target, as disclosed in U.S. Pat. No. 9,960,021 B1, issued May 1, 2018, and/or U.S. Pat. No. 11,618,943 B2, issued Apr. 4, 2023.

In at least some embodiments, the roughened portion has an average roughness of at least 63.5 microns, (2500 microinches) Ra. In at least some embodiments, the roughened portion further comprises a series of peaks separated by valleys, wherein the peaks have an average height of at least 100 nm above the valleys. In some embodiments, the roughened portion is flow formed. In some embodiments, the roughened portion comprises a knurled pattern, for example, a diamond knurled pattern.

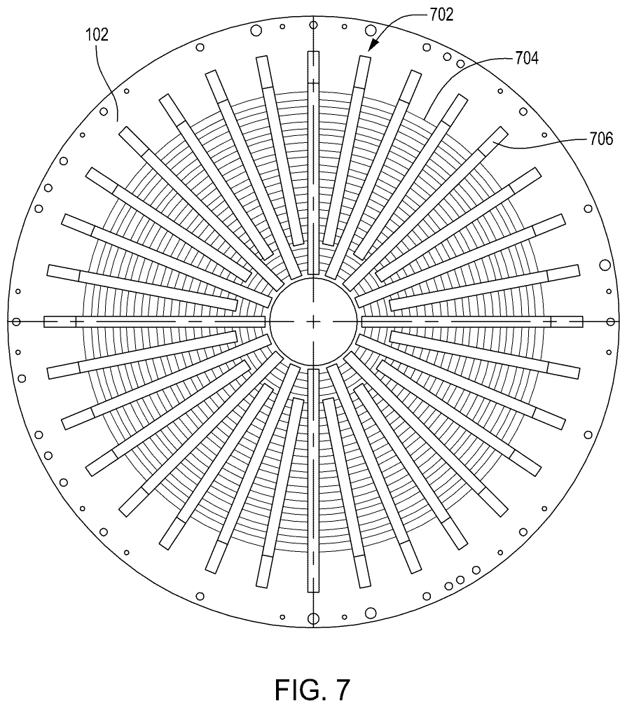

As depicted in FIG. 7, in embodiments the underside of the backing plate 102 further comprises a plurality of cooling channels 702 disposed therein. In embodiments, the plurality of cooling channels 702 comprise a plurality of concentric rings 704. In embodiments, the plurality of cooling channels 702 comprise a plurality of linear channels 706, each extending radially outward from an inner portion 708 to an outer portion 701 of the backing plate 102.

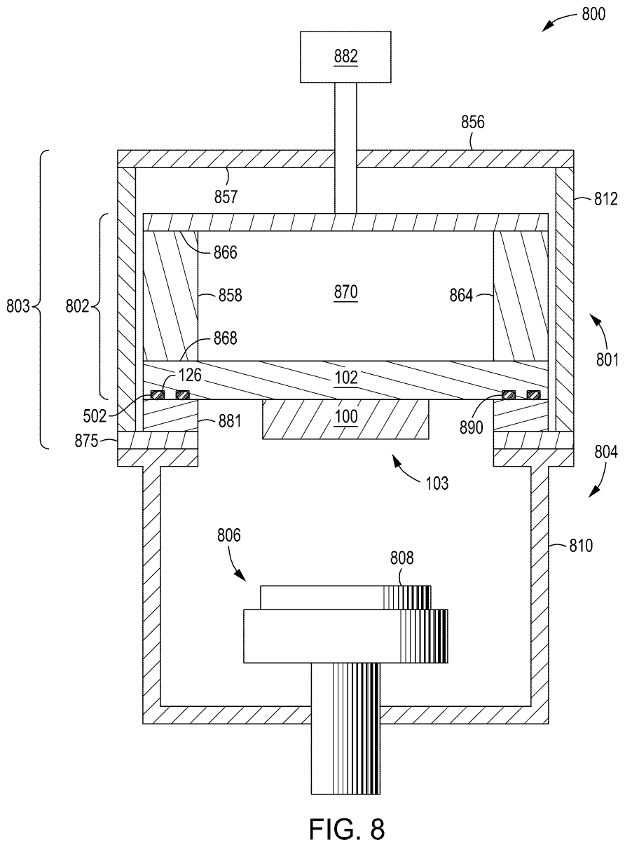

As depicted in FIG. 8, in embodiments a PVD chamber includes the sputtering target 100 mounted on a backing plate 102, collectively referred to as a target assembly 103. A simplified schematic cross-sectional view of FIG. 8 depicts a physical vapor deposition (PVD) chamber 800 having a target assembly 103 in accordance with embodiments disclosed herein.

In embodiments, the PVD chamber 800 includes a chamber lid 801 disposed atop a process chamber 804 and removable from the process chamber 804. The chamber lid 801 may include an inner assembly 802 and an outer grounding assembly 803. The process chamber 804 contains a substrate support 806 for receiving a substrate 808 thereon. The substrate support 806 may be located within a lower grounded enclosure wall 810, which may be a chamber wall of the process chamber 804. The lower grounded enclosure wall 810 may be electrically coupled to the outer grounding assembly 803 of the chamber lid 801 such that an RF return path is provided to an RF power source 882 disposed above the chamber lid 801.

The chamber lid 801 generally includes the outer grounding assembly 803 disposed about the inner assembly 802. The outer grounding assembly 803 may include a grounding plate 856 having a first surface 857 that may be generally parallel to and opposite a backside of the inner assembly 802. A grounding shield 812 may extend from the first surface 857 of the grounding plate 856 and surround the inner assembly 802. The outer grounding assembly 803 may include a support member 875 to support the inner assembly 802 within the outer grounding assembly 803.

The inner assembly 802 may include a source distribution plate 858 opposing a backside of the target assembly 103 and electrically coupled to the target assembly 103 along a peripheral edge of the target assembly 103. As discussed above, the target assembly 103 comprises the sputtering target 100 to be deposited on a substrate, such as the substrate 808 during sputtering. The sputtering target 100 may be comprised of metal, metal oxide, metal alloy, or the like. In some embodiments, the target assembly 103 includes a backing plate 102 to support the sputtering target 100. The sputtering target 100 may be disposed on a substrate support facing side of the backing plate 102 as illustrated in FIG. 8. The backing plate 102 may comprise a conductive material, such as copper, copper-zinc, copper-chrome, or the same material as the target, such that RF and DC power can be coupled to the sputtering target 100 via the backing plate 102. Alternatively, the backing plate 102 may be non-conductive and may include conductive elements (not shown) such as electrical feedthroughs or the like. The backing plate 102 includes a grooves to retain sealing element 890, and one or more recesses 126 to retain low friction pads 502(s).

In some embodiments, the support member 875 may be coupled to a lower end of the grounding shield 812 proximate an outer peripheral edge of the support member 875 and extends radially inward to support a seal ring 881, and the inner assembly 802. The seal ring 881 may be a ring or other annular shape having a desired cross-section. The seal ring 881 may include two opposing planar and generally parallel surfaces to facilitate interfacing with backing plate 102 of target assembly 103 of the inner assembly 802, on a first side of the seal ring 881 and with the support member 875 on a second side of the seal ring 881. The seal ring 881 may be made of a dielectric material, such as ceramic. The seal ring 881 may insulate the inner assembly 802 from the outer grounding assembly 803. The seal ring 881 interfaces with backing plate 102 via bearing surfaces of the low friction pads 502. In addition, the sealing element 890 disposed in grooves of backing plate 102 also contacts seal ring 881 to form a vacuum seal between backing plate 102 and seal ring 881.

A conductive member 864 may be disposed between a source distribution plate 858 and the backside of the target assembly 103 to propagate RF energy from the source distribution plate to the peripheral edge of the target assembly 103. The conductive member 864 may be cylindrical, with a first end 866 coupled to a target-facing surface of the source distribution plate 858 proximate the peripheral edge of the source distribution plate 858 and a second end 868 coupled to a source distribution plate-facing surface of the target assembly 103 proximate the peripheral edge of the target assembly 103. In some embodiments, the second end 868 is coupled to a source distribution plate facing surface of the backing plate 102 proximate the peripheral edge of the backing plate 102. In some embodiments, the backing plate 102 may be coupled to the second end 868 of conductive member 864 via one or more fasteners.

The inner assembly 802 may include a cavity 870 disposed between the backside of the target assembly 103 and the source distribution plate 858. The cavity 870 may at least partially house a magnetron assembly. The cavity 870 is at least partially defined by the inner surface of the conductive member 864, a target facing surface of the source distribution plate 858, and a source distribution plate facing surface (e.g., backside) of the target assembly 103 (or backing plate 102). In some embodiments, the cavity 870 may be at least partially filled with a cooling fluid, such as water (H₂O) or the like.

While the foregoing is directed to embodiments of the present disclosure, other and further embodiments of the disclosure may be devised without departing from the basic scope thereof.

1. A sputtering target, comprising:
a material to be sputtered having a central planar region, the central planar region having a tapered peripheral edge region which terminates at an upper outer edge, wherein a portion of the tapered peripheral edge comprises a roughened portion have an average roughness (Ra) of greater than or equal to 60 micrometers.

2. The sputtering target of claim 1, wherein a thickness of the central planar region is greater than a thickness of the upper outer edge.

3. The sputtering target of claim 2, further comprising a lower outer edge, wherein the upper outer edge overhangs the lower outer edge.

4. The sputtering target of claim 1, further comprising:
a backing plate having the material to be sputtered disposed thereon and having a diameter greater than that of the material to be sputtered, wherein the roughened portion further includes a peripheral portion of the backing plate located adjacent to, and surrounding the tapered peripheral edge region, and having an average roughness (Ra) of greater than or equal to 63.5 micrometers.

5. The sputtering target of claim 4, wherein the upper outer edge overhangs a portion of the backing plate.

6. The sputtering target of claim 4, wherein the backing plate further comprises a plurality of recesses formed therein, dimensioned and arranged to accommodate a plurality of low-friction pads partially disposed in the plurality of recesses.

7. The sputtering target of claim 1, wherein the roughened portion comprises a series of peaks separated by valleys, the series of peaks having an average height of at least 100 nm above the valleys.

8. The sputtering target of claim 1, wherein the roughened portion is flow formed.

9. The sputtering target of claim 1, wherein the roughened portion has an average roughness (Ra) of greater than or equal to 63.5 micrometers.

10. The sputtering target of claim 1, wherein the roughened portion comprises a knurled pattern.

11. The sputtering target of claim 1, wherein the roughened portion comprises a diamond knurled pattern.

12. The sputtering target of claim 1, further comprising a plurality of cooling channels disposed therein.

13. The sputtering target of claim 12, wherein the plurality of cooling channels comprise a plurality of concentric rings.

14. The sputtering target of claim 12, wherein the plurality of cooling channels comprise a plurality of linear channels, each extending radially outward from an inner portion to an outer portion of the sputtering target.

15. A sputtering target, comprising:
a material to be sputtered including a central planar region having a tapered peripheral edge which terminates at an upper outer edge located above a lower outer edge of the central planar region;
a backing plate having the material to be sputtered disposed thereon and comprising a peripheral region located adjacent to and surrounding the lower outer edge of the material to be sputtered, wherein a thickness of the central planar region is greater than a thickness of the upper outer edge, wherein the upper outer edge overhangs a portion of the peripheral region comprising the material to be sputtered; and
a roughened portion comprising a portion of the tapered peripheral edge and at least a portion of the peripheral region comprising the material to be sputtered, having an average roughness (Ra) of greater than or equal to 60 micrometers.

16. The sputtering target of claim 15, further comprising a plurality of cooling channels disposed therein, the plurality of cooling channels comprise a plurality of concentric rings, a plurality of linear channels, each extending radially outward from an inner portion to an outer portion of the sputtering target, or a combination thereof.

17. The sputtering target of claim 15, wherein the roughened portion is flow formed, and comprises a series of peaks separated by valleys, the series of peaks having an average height of at least 100 nm above the valleys.

18. The sputtering target of claim 15, wherein the roughened portion has an average roughness (Ra) of greater than or equal to 63.5 micrometers.

19. The sputtering target of claim 15, further comprising a plurality of recesses formed into the backing plate dimensioned and arranged to accommodate a plurality of low-friction pads to be partially disposed in the plurality of recesses.

20. A substrate processing apparatus, comprising:
a chamber body;
a lid disposed atop the chamber body; and
a target assembly coupled to the lid, the target assembly including a sputtering target according to claim 1.
